(19) United States
(12) Patent Application Publication
(10) Pub. No.: US 2006/0097392 A1
(43) Pub. Date: May 11, 2006

(54) Wafer structure, chip structure and bumping process

(75) Inventor: Shyh-Ing Wu, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/265,088

(22) Filed: Nov. 3, 2005

(30) Foreign Application Priority Data
Nov. 5, 2004 (TW) 093133763

(51) Int. Cl. H01L 23/48

(52) U.S. Cl. 257/738

(57) ABSTRACT

A kind of wafer structure including a plurality of chip, first passivation layer, a plurality of buffer pad, second passivation layer, and a plurality of bump. Each chip has an active surface, on which a plurality of bonding pad are disposed. The first passivation layer is disposed on the active surface of the chips. First passivation layer has a plurality of first openings, each of which exposes a bonding pad. The buffer pads are disposed on the first openings and the surrounding first passivation layer. The buffer pads are electrically connected with bonding pad. The second passivation layer is disposed on the first passivation layer. The second passivation layer has a plurality of second openings, each of which exposes a buffer pad. The bumps are disposed inside the second openings and electrically connected with buffer pads.

The present application is based on, and claims priority from, Taiwanese Patent Application Number 093133763, filed Nov. 5, 2004, the disclosure of which is incorporated by reference herein in its entirety.

### BACKGROUND OF THE INVENTION

1. Field of the Invention

This invention relates to a kind of wafer structure, chip structure, and bumping process, and more particularly to a kind of wafer structure, chip structure and bumping process with buffer pad between the bump and bonding pad.

2. Description of the Related Art

In the contemporary information society, the market of multimedia application has been expanding at a tremendous speed. The development of IC packaging technology moves in accordance with the digitalization, networking, local-connecting, and human-friendliness of digital devices. To satisfy the above requirements, electrical components have to be enhanced with high-speed processing, multi-function, integration, lightweight, and low price, pushing IC packaging technology toward microstructure and high density. Consequently, high density packaging technologies such as Ball Grid Array (BGA), chip-Scale Package (CSP), Flip chip (F/C), and Multi-chip Module (MCM) have been introduced. The density of IC packaging refers to the number of pins contained in per unit area. In high density IC packaging, shortening of distribution leads to the improvement in speed of signal transmission; therefore the application of bump becoming the most popular in high density packaging.

FIG. 1 is the cross sectional view of wafer structure with bump of prior art. FIG. 1 shows a wafer structure 100 of prior art that comprises a wafer 110, one nitride 120, one polyimide 130, a plurality of under bump metallurgies (UBM) 140 and a plurality of bumps 150. Here, FIG. 1 only illustrates part of wafer 110, a UBM 140, and a bump 150. Wafer 110 has an active surface S1, on which a plurality of bonding pads 112 are disposed (FIG. 1 only illustrates one). Nitride 120 is covered on the active surface S1 of wafer 110. Nitride 120 has a plurality of openings O1, and each opening O1 reveals part of bonding pad 112. Polyimide 130 is implemented on nitride 120. Polyimide 130 has a plurality of openings O2, and each opening O2 corresponds to an opening O1. Each UBM 140 is disposed on an opening O2 and the corresponding opening O1. Each bump 150 is disposed on a UBM 140. Bump 150 is electrically connected with bonding pad 112 via UBM 140.

However, in wafer structure 100 of prior art, seam C1 may often be generated in the interface between polyimide 130 and bump 150. Besides, seam C1 may further grow downward to bonding pad 112, eventually break bonding pad 112 and cause invasion of air and humidity inside wafer 110, reducing reliability of wafer structure 100.

### SUMMARY OF THE INVENTION

It is an object of the present invention to provide a wafer structure that is suitable for the enhancement of reliability in wafer structure.

It is another object of the present invention to provide a chip structure that is suitable for the enhancement of reliability in chip structure.

It is still another objective of the present invention to provide a bumping process that is suitable for the enhancement of reliability in chip structure.

The present invention presents a kind of wafer structure comprising a plurality of chips, a first passivation layer, a plurality of buffer pads, a second passivation layer, and a plurality of bumps. Each chip has an active surface, on which a plurality of bonding pads are disposed. The first passivation layer is implemented on the active surface of the chip. The first passivation layer has a plurality of first openings, and each first opening exposes a bonding pad. Buffer pad is disposed on the first opening and the surrounding first passivation layer, and is electrically connected with bonding pad. The second passivation layer is disposed on the first passivation layer. The second passivation layer has a plurality of second opening; each second opening exposes a buffer pad. Bump is disposed inside the second opening and is electrically connected with the buffer pad.

The present invention further presents a kind of chip structure, which includes a chip, a first passivation layer, a plurality of buffer pad, a second passivation layer, and a plurality of bump. The chip has an active surface, on which a plurality of bonding pad is disposed. The first passivation layer is disposed on the active surface of the chip. The first passivation layer has a plurality of first opening, and each first opening exposes a bonding pad. Buffer pad is disposed on the first opening and its surrounding first passivation layer and is electrically connected with the bonding pad. The second passivation layer is disposed on the first passivation layer. The second passivation layer has a plurality of second openings; each second opening exposes a buffer pad. Bump is disposed inside the second opening and is electrically connected with the buffer pad.

In the above-mentioned wafer structure and chip structure, the projected area of contact surface between bump and passivation on the active surface is smaller than the projected area of buffer pad.

Besides, the wafer structure and chip structure, for example, further include a plurality of UBMs disposed between the bumps and buffer pads. Buffer pads may be made of aluminum.

In addition, the first passivation layer may include a nitride and a polyimide. Nitride is disposed on the active surface of the chip, and polyimide is disposed on the nitride.

Moreover, second passivation layer may be made of polyimide.

This invention further presents a kind of bumping process, in which a wafer is provided with a plurality of bonding pads on the surface. Then, a first passivation layer is formed on the wafer. The first passivation layer has a plurality of first openings; each first opening reveals a bonding pad. Further, a buffer pad is formed on each of the bonding pad inside the first opening and on the surrounding area of first passivation layer. Then, a second passivation layer is formed on the first passivation layer. The second passivation layer has a plurality of second openings; each second opening reveals a buffer pad. Finally, a bump is formed on each of the buffer pad exposed by the second opening.

In this bumping process, the projected area of contact surface between bump and second passivation layer on active surface should be smaller than the projected area of buffer pad on active surface.

Besides, after providing a wafer and before forming the first passivation layer, a Redistribution Layer (RDL) may be formed on the wafer, and the bonding pad is disposed on the Redistribution Layer.

Moreover, after forming the second passivation layer and before forming the bump, a UBM (Under bump Metallurgy) may be formed on the buffer pad exposed by the second opening, and the bump is formed on the UBM.

In sum, the wafer structure, chip structure and bumping process in the present invention includes a buffer pad implemented between bonding pad and bump, so as to prevent that the seam generated in the interface between the second passivation layer and bump from accessing further than the buffer pad. Hence, reliability in the wafer structure and chip structure of the present invention can be enhanced.

Other objects, advantages, and novel features of the present invention will become more apparent from the following detailed description of the preferred embodiments when taken in conjunction with the accompanying drawings.

### BRIEF DESCRIPTION OF THE DRAWING

FIG. 1 is a cross sectional view of wafer structure with bump of prior art.

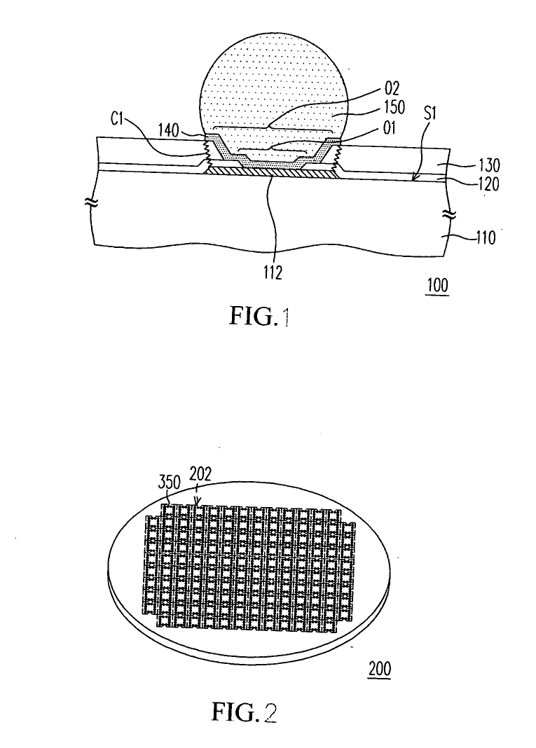

FIG. 2 is a cross sectional view of wafer structure according to a preferred embodiment of the present invention.

FIG. 3 is a cross sectional view of chip structure according to a preferred embodiment of the present invention.

FIG. 4 is the cross sectional view alone section line I-I′ in chip structure of FIG. 3.

FIG. 5˜FIG. 10 are cross sectional views of bumping process according to an embodiment of the present invention.

### DETAILED DESCRIPTION OF THE PREFERRED EMBODIMENT

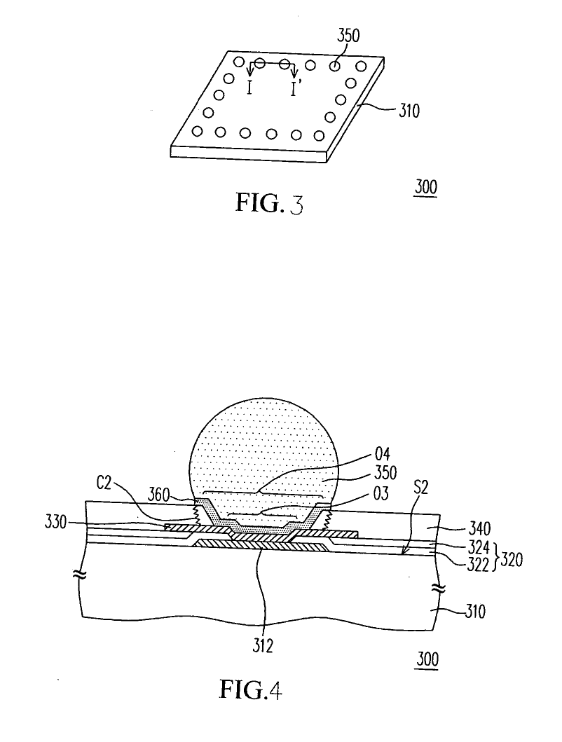

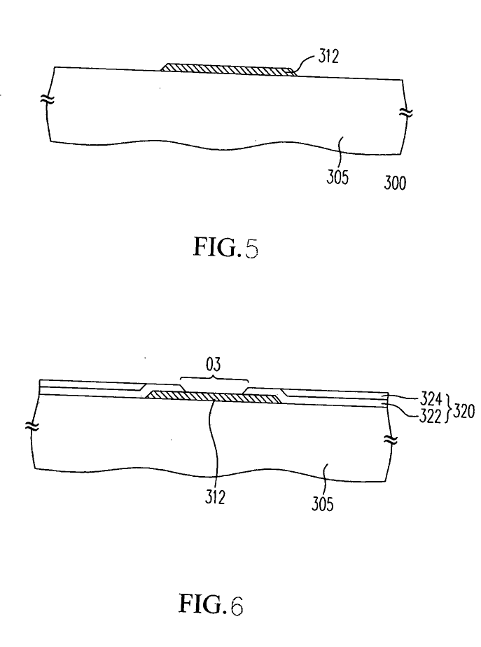

FIG. 2 illustrates a wafer structure according to a preferred embodiment of the present invention, and FIG. 3 illustrates a chip structure according to a preferred embodiment of the present invention. In FIG. 2, wafer structure 200 of the embodiment of the present invention can be divided into a plurality of chip units 202. After sawing of wafer structure 200, each chip unit 202 becomes a chip structure 300, as shown in FIG. 3. In other words, after sawing, the wafer structure 200 is identical to the chip structure 300 in the preferred embodiment of the present invention. Chip structure 300 will be detailed as follows while wafer structure 200 will be omitted.

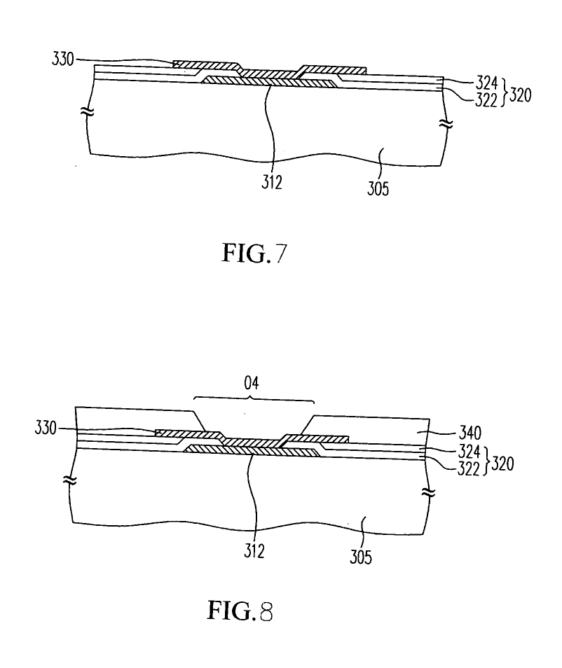

FIG. 4 is the cross sectional view of chip structure in FIG. 3 along section line I-I′. In FIG. 3 and FIG. 4, chip structure 300 of this embodiment mainly constitutes a chip 310, a passivation layer 320, a plurality of buffer pads 330, a passivation layer 340 and a plurality of bumps 350.

Chip 310 has an active surface S2, on which a plurality of bonding pads 312 are disposed. Chip 310 is mainly composed of silicon, and bonding pad 312 may be made of aluminum or other conducting materials. Passivation 320 is disposed on the active surface S2 of chip 310. Passivation 320 has a plurality of openings O3, and each opening O3 reveals a bonding pad 312. Here, opening O3 may expose only the central part of bonding pad 312; in other words, passivation 320 may cover the surrounding area of bonding pad 312. Besides, passivation 320 may include a nitride 322 and a polyimide 324. Nitride 322 is disposed on the active surface S2 of chip 310, and polyimide 324 is disposed on nitride 322. Besides, nitride 322 may also be replaced by material layer composed of nitride, silica, silicon dioxide, or other insulating materials, and polyimide 324 may also be replaced by material layer composed of polymer material or other insulating materials.

Buffer pad 330 is disposed on opening O3 and the surrounding area of passivation 320, electrically connected with bonding pad 312. Buffer pad 330 may be made of metals or other insulating and unbreakable materials; aluminum is a preferred material for buffer pad 330.

Passivation 340 is disposed on passivation 320. Passivation 340 has a plurality of openings O4, and each opening O4 exposes a buffer pad 330. Here, opening O4 may revleal only the central part of buffer pad 330; in other words, passivation 340 may cover the surrounding area of buffer pad 330. Passivation 340 may be made of polymer material or other insulating materials, and polyimide and acrylic or Benzocyclobutene (BCB) are two of the preferred solution for passivation 340.

Bump 350 is disposed inside opening O4 and electrically connected with buffer pad 330. Bump 350 may be made of SnCu, SnAgCu(SAC) or other adequate conducting materials. And, the projected area of contact surface between bump 350 and passivation 340 on active surface S2 is recommended to be smaller than the projected area of buffer pad 330 on active surface S2.

Besides, chip structure 300 may further include a plurality of UBMs 360, implemented between bump 350 and buffer pad 330. UBM 360 may be composed of three metal layers (not illustrated) of adhesion layer/barrier layer/wetting layer. Adhesion layer is intended to enhance the adherence between UBM 360 and buffer pad 330, barrier layer is aimed to prevent mobile ions from penetrating UBM 360 and expand into chip 310, and wetting layer is aimed to enhance the adherence between UBM 360 and bump 350.

Please refer to FIG. 2 to FIG. 4 as well. Wafer structure 200 (illustrated in FIG. 2) and chip structure 300 (illustrated in FIG. 3) in the present invention allocates a buffer pad 330 between bonding pad 312 and bump 350. Therefore, when seam C2 is generated in the interface between passivation 340 and bump 350, even if seam C2 grows downward, buffer pad 330 will block it outside from the active surface. Therefore, buffer pad 330 can prevent seam C2 from damaging bonding pad 312 and air or water from invading inside the chip 310.

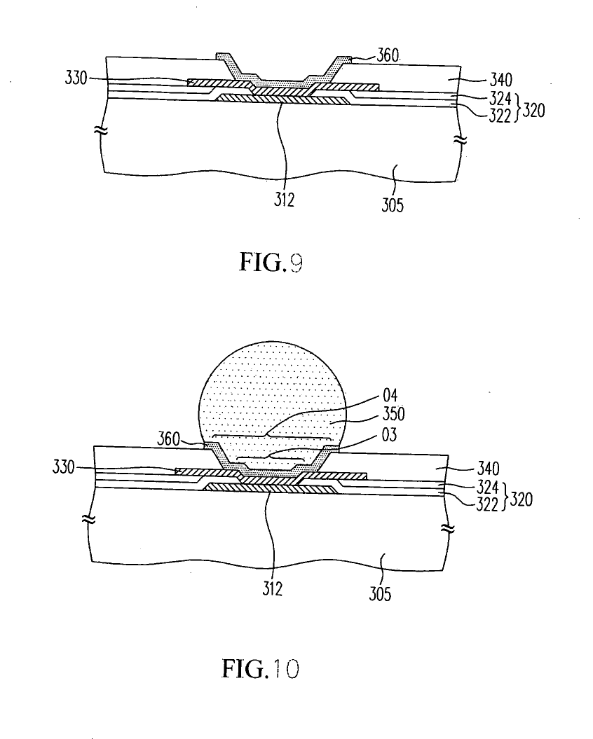

One of the embodiments in the present invention is a bumping process, which is suitable for the applications as per illustrated in FIG. 2 and in wafer structure 200 and chip structure 300 of FIG. 3. FIG. 5˜FIG. 10 are the cross sectional views of bumping process according to an embodiment of the present invention. Identical structures in FIG. 5˜FIG. 10 and FIG. 4 will be denoted with the same symbols.

In FIG. 5, bumping process in this embodiment first provides a wafer 305, which has a plurality of bonding pads 312. In FIG. 5, only a part of wafer 305 and one bonding pad 312 are illustrated.

In response to chip structures with different junction location on the surface of wafer 305, an optional redistribution layer (not illustrated) may be created, and bonding pad 312 is located on the redistribution layer.

In FIG. 6, a passivation 320 is formed on wafer 305. Passivation 320 has a plurality of openings O3, and each opening O3 exposes a bonding pad 312. On the other hand, passivation 320 may include a nitride 322 and a polyimide 324. Nitride 322 is disposed on the surface of wafer 305, and polyimide 324 is disposed on nitride 322. Besides, nitride 322 may also be replaced by material layer composed of nitride, silica, silicon dioxide or other insulating materials, and polyimide 324 may be replaced by material layer composed of polymer material or other insulating materials.

Further, in FIG. 7, a buffer pad 330 is formed on the bonding pad 312 inside each opening O3 and the surrounding passivation 320. Projected area of contact surface between bump 350 and passivation 340 on the surface of wafer 305 is recommended to be smaller than the projected area of the buffer pad 330 on the surface of wafer 305.

In FIG. 8, a passivation 340 is formed on passivation 320. Passivation 340 has a plurality of openings O4, and each opening O4 exposes a buffer pad 312.

Then, in FIG. 9, a UBM 360 on the buffer pad 330 may be further formed inside the opening O4.

Finally, in FIG. 10, a bump 350 is formed on the buffer pad 330 inside each of the opening O4.

In sum, the wafer structure, chip structure and bumping process of the present invention include a buffer pad disposed between bonding pad and bump, so that the reliability of wafer structure and chip structure can be further enhanced.

Although the invention has been explained in relation to its preferred embodiment, it is to be understood that many other possible modifications and variations can be made without departing from the spirit and scope of the invention as hereinafter claimed. Further, the present invention is defined by the patent claims.

1. A wafer structure with a plurality of chips, comprising:
an active surface disposed on each chip with a plurality of bonding pads on the surface;
a first passivation layer, which is disposed on said active surface of said chips and has a plurality of first openings that reveal each one of said bonding pads;
a plurality of buffer pads, each of which is disposed on said bonding pad revealed by said first opening and further on the surrounding area of said first passivation layer, as well as electrically connected with said bonding pad;
a second passivation layer, which is disposed on said first passivation layer and has a plurality of second openings, each of which reveals one of said buffer pads;
a plurality of bumps, each of which is disposed inside said second opening and electrically connected with said buffer pad, wherein the projected area of contact surface between each bump and said second passivation layer on said active surface is smaller than the projected area of said buffer pad on said active surface; and
a plurality of UBMs, each of which is disposed on the buffer pad exposed by said second opening and further on the surrounding area of said second passivation layer, locating between said bump and said buffer pad and fulfilling the contact surface between said bump and said second passivation layer on said active surface.

2. The wafer structure as claimed in claim 1, wherein the buffer pads are made of aluminum.

3. The wafer structure as claimed in claim 1, wherein the first passivation layer further comprises:
a nitride, disposed on said active surface of said chip; and
a polyimide, disposed on said nitride.

4. The wafer structure as claimed in claim 1, wherein the said second passivation layer is made of polyimide.

5. A chip structure, comprising:
an active surface disposed on a chip with a plurality of bonding pads disposed on the surface;
a first passivation layer disposed on said active surface of said chip, wherein said first passivation layer has a plurality of first openings and exposes each one of said bonding pads;
a plurality of buffer pads, each of which is disposed on said bonding pad exposed by the first opening and the surrounding area of first passivation layer, as well as electrically connected with said bonding pads;
a second passivation layer, which is disposed on said first passivation layer and has a plurality of second openings, each of which reveals one of said buffer pads;
a plurality of bumps, each of which is disposed inside said second opening and electrically connected with said buffer pad, wherein the projected area of contact surface between each of said bump and said second passivation layer on the active surface is smaller than the projected area of said buffer pad on said active surface; and
a plurality of UBMs, each of which is disposed between said bump and said buffer pad, fulfilling the contact surface between said bump and said second passivation layer on said active surface.

6. The chip structure as claimed in claim 5, wherein said buffer pads are made of aluminum.

7. The chip structure as claimed in claim 5, wherein said first passivation layer further comprises:
a nitride, which is disposed on said active surface of said chip; and
a polyimide, which is disposed on said nitride.

8. The chip structure as claimed in claim 5, wherein said second passivation layer is made of polyimide.
